(19) United States
(12) Patent Application Publication
(10) Pub. No.: US 2003/0007325 A1
(43) Pub. Date: Jan. 9, 2003

(54) Use of a sealed insulated container for a personal computer coupled with a method for removal of waste heat generated by the encased electronics

(76) Inventors: Erik Andrew Thunem, Faribault, MN (US); Cabot Briggs Thunem, Faribault, MN (US)

Correspondence Address: Cabot Thunem, 3411 Culver Trail, Faribault, MN, 55021, US

(21) Appl. No.: 09/760,519

(22) Filed: Jul. 9, 2001

(51) Int. Cl. H05K 5/00

(52) U.S. Cl. 361/687

(57) ABSTRACT

This patent application describes a method to reduce noise and protect a personal computer from ambient contamination through use of a sealed insulated container. The method describes the approach to sealing the container while addressing the removal of waste heat from inside the sealed insulated container. The end result is a computer with reduced noise along with virtual elimination of problems with dirt, insects, and other debris damaging the computer. The method also describes use of heat pump technology to subcool computer components resulting in increased reliability and higher operating speeds.

### CROSS-REFERENCE TO RELATED APPLICATIONS

Not Applicable

### STATEMENT REGARDING FEDERALLY SPONSORED RESEARCH OR DEVELOPMENT

No federally sponsored research or development was involved.

### REFERENCE TO A MICROFICHE APPENDIX

No computer program or microfiche are included

### BACKGROUND OF THE INVENTION

Historically personal computers have been enclosed in a container that provided support to the internal electronics and peripherals. Heat released from the internal devices was removed by moving ambient air through the interior of the container with fans. As personal computer design has advanced the cooling needs have increased with a subsequent increase in cooling air requirements. This design approach has resulted in a significant accumulation of dust, insects, and other debris within the container occasionally resulting in equipment malfunction. The growth in cooling requirements has also resulted in higher decibel levels from the fans for movement of air through the container.

### BRIEF SUMMARY OF THE INVENTION

The invention consists of a closed insulated container coupled with a method for removing the waste heat generated by the electronics and peripherals inside the container. The closed insulated container keeps dirt, insects, and other debris from contact with the electronics and peripherals. Further, the insulation reduces noise problems associated with the computer cooling system. The heat is removed indirectly by either a circulating fluid or a heat pump. Use of a heat pump allows subcooling of the interior of the container resulting in lower operating temperatures for components.

### BRIEF DESCRIPTION OF THE SEVERAL VIEWS OF THE DRAWING

No drawings are required or included.

### DETAILED DESCRIPTION OF THE INVENTION

The personal computer consists of a motherboard to which are directly attached a CPU, memory, and various I/O cards. Peripherals commonly attached or required are a power supply, hard drives, removable drives, and heat removal devices such as heat sinks and fans. Some systems include water cooling, Peltiers, or Joule-Thompson devices for cooling of a specific internal portion of the electronics (usually the CPU). The total is enclosed in a container with opening to the ambient air. Cooling air is moved through the container to remove the waste heat from the heat sinks and heat rejection (hot) end of the water cooling, Peltier, or Joule-Thompson devices.

Using sheet metal and an insulating material build a closed metal container large enough to allow attachment of all required components inside the container. On one side of the container the required cables must pass through the container to allow power input, output to ancillary devices such as printers, viewing screen, telephone lines or LANs and the heat rejection hot end.

Typically, access is provided by removal of one complete side. When all internal components are installed, connected, and the proper operation of the system verified, the container is sealed.

All openings must be sealed to contain noise. A foaming, insulating sealant was used on the prototype. The expanding foam effectively sealed all wiring and joints preventing incursion of moisture laden ambient air. Exclusion of moisture reduces potential for condensation or other moisture damage in humid climates.

If subcooling is included by addition of a heat pump, the interior of the container must include a dessicant or the gas inside the container must be dried by other means. The container must be sealed to minimize exposure to ambient air. If moisture is allowed into the subcooled system condensation can occur. The simplest method is to evacuate the container followed by injection of nitrogen. Alternatively a dessicant can be inserted into the container to control humidity.

Working fluid (typically water) cooling to remove heat from the container consists of two heat exchangers along with a pump to circulate the fluid. Use of a liquid other than water can reduce corrosion in the cooling loop and reduce freezing in colder climates. The heat exchanger located inside the container must be sized to accommodate the heat generated by the computer equipment located inside the container. The heat exchanger located outside the container must be sized large enough to reject the heat from the interior to the ambient air. The pump must be large enough to circulate sufficient working fluid to remove the heat from the container.

When a heat pump is used to remove heat from the container, the heat pump must be sized large enough to remove all heat generated by the computer components and peripherals located inside the container. By providing a heat pump of sufficient capacity, the computer operating temperature can be lower below ambient. At lower temperatures electronic component life is typically extended. In addition, the CPU can be overclocked significantly without damage due to excess temperature. When using a heat pump the cold end must be located inside the container and the hot end must be located outside the container in order to reject the heat to the ambient surroundings.

Within the container, cooling is improved by locating a device to circulate the fluid within the container around the components. With a gas, a single fan appropriately located within the container is adequate. If the container is filled with a liquid, either a circulating pump or an eductor should be included within the container to move the liquid. Failure to provide sufficient circulation can result in local hot spots within the container with the potential for damage to the components.

The design of the system can be simplified somewhat by locating some components outside of the sealed container. The power supply and removable drives located outside the container reduce the heat load in the heat transfer system and lower the complexity of providing a sealed environment.

1. What we claim as our invention is a computer in a sealed container with heat removal to reduce noise and isolate the computer from ambient conditions.
